(19) United States
(12) Patent Application Publication
(10) Pub. No.: US 2004/0194988 A1
(43) Pub. Date: Oct. 7, 2004

(54) EMI-shielding assembly and method for making same

(76) Inventor: Ga-Lane Chen, Fremont, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/807,210

(22) Filed: Mar. 22, 2004

(30) Foreign Application Priority Data
Mar. 21, 2003 (TW) 92106305

(51) Int. Cl. H05K 9/00

(52) U.S. Cl. 174/35 MS

(57) ABSTRACT

A method for manufacturing an EMI-shielding assembly having a substrate comprises the steps of: (a) providing oxygen plasma to clean the substrate; (b) ion plating the cleaned substrate with an adhesion layer comprising nickel; (c) ion plating the plated substrate with a metal shielding layer comprising copper; and (d) ion plating the plated substrate with a corrosion-resistant layer comprising stainless steel. The EMI-shielding assembly made by this method has a very firm adhesion between the substrate and the metal layers. Moreover, the EMI-shielding assembly has superb characterisitics for shielding EMI since the substrate has a more uniform shielding layer. In addition, this method is very suitable for making an EMI-shielding object which has an irregular shape.

### BACKGROUND OF THE INVENTION

1. Field of the Invention

The present invention relates to an EMI-shielding assembly and a method for making the same.

2. Related Art

In many portable electronic devices such as mobile phones and personal digital assistants (PDAs), different electronic components often interfere with each other by producing electromagnetic signals. To solve this problem, metal enclosures or metal-coated plastic enclosures are often welded to package some electronic components so that they will not interfere with other electronic components. While welding the metal enclosures or metal-coated plastic enclosures increases weight and cost of the electronic devices, this is adverse to miniaturization of the electronic devices.

Accordingly, an electronic component needs to be protected from Electromagnetic Interference (EMI) is oftentimes electroplated with a layer of metal on a plastic substrate thereof. For example, a printed circuit board (PCB) substrate can be partially electroplated with a layer of metal materials to protect some sensitive electronic components thereon from EMI.

However, utilizing this kind of electroplating has some disadvantages. The coating is susceptible to being degraded due to weak adhesion between the coating and the PCB substrate. Moreover, the electroplating is not suitable for some irregular objects, since the irregular objects are difficult to be evenly electroplated. As a result, the coated irregular objects have poor capability of EMI-shielding, which affects operations of the electronic components severely.

Accordingly, an improved EMI-shielding assembly and a method for making the same which overcome the above-mentioned problems is desired.

### BRIEF SUMMARY OF THE INVENTION

Accordingly, an object of the present invention is to provide an EMI-shielding assembly which has a uniform coating thereon and has a firm adhesion between the coating and a substrate thereof.

Another object of the present invention is to provide a method for manufacturing the above-mentioned EMI-shielding assembly.

To achieve the above-mentioned objects, a method for manufacturing an EMI-shielding assembly having a substrate comprises the steps of: (a) providing oxygen plasma to clean the substrate; (b) ion plating the cleaned substrate with an adhesion layer comprising nickel; (c) ion plating the plated substrate with a metal shielding layer comprising copper; and (d) ion plating the plated substrate with a corrosion-resistant layer comprising stainless steel. The EMI-shielding assembly made by this method has a very firm adhesion between the substrate and the metal layers. Moreover, the EMI-shielding assembly has superb characterisitics for shielding EMI since the substrate has a more uniform shielding layer. In addition, this method is very suitable for making an EMI-shielding object which has an irregular shape.

Other objects, advantages and novel features of the present invention will be drawn from the following detailed description of a preferred embodiment of the present invention with the attached drawings, in which:

### BRIEF DESCRIPTION OF THE DRAWINGS

FIG. 1 is a schematic view of an apparatus for carrying out a method for manufacturing an EMI-shielding assembly according to the present invention;

FIG. 2 is a flow chart of the method according to the present invention; and

FIG. 3 is a cross-sectional view of a portion of the EMI-shielding assembly made by the method according to the present invention.

### DESCRIPTION OF THE PREFERRED EMBODIMENT

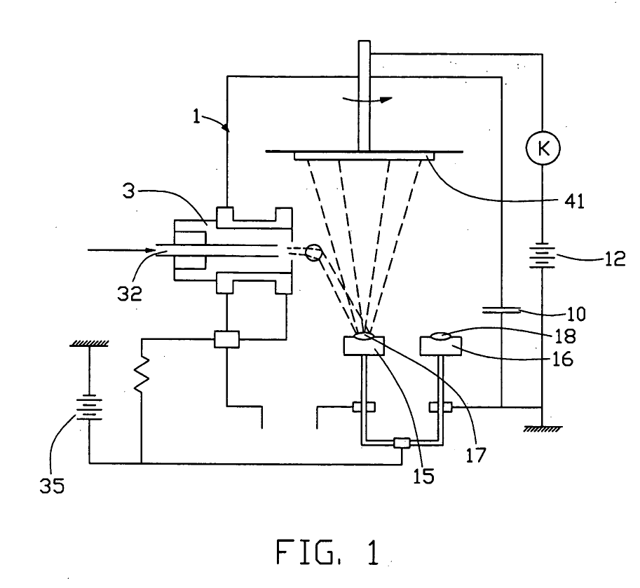

FIG. 1 shows an apparatus for treatment of a PCB (printed circuit board) substrate 41 to form an electronic component with EMI-shielding function. The apparatus includes a vacuum chamber 1, a vacuum pump (not shown) connected to the vacuum chamber 1, and an electron gun 3.

The electron gun 3 is arranged on a left sidewall (not labeled) of the vacuum chamber 1 for emitting electron with high energy. The electron gun 3 comprises a cylindrical cartrige 32, allowing noble gas, for example, argon gas, to pass through. The electron gun 3 is electrically connected to a power source 35 which is applied high voltage to the same. A pair of crucibles 15 and 16 is arranged at the bottom of the vacuum chamber 1 for accommodating different metal materials such as nickel 17 and copper 18. A gas inlet 10 is defined through a right sidewall of the vacuum chamber 1 so that a predetermined reactive gas can be introduced therethrough. The PCB substrate 41 is arranged within the vacuum chamber 1, as shown in FIG. 1, and is connected with a substrate accelerating power source 12, which is adapted to apply a voltage to the same. The PCB substrate 41 is made of plastic material, for example, polycarbonate (PC). Besides, a magnetic field (not shown) is arranged within the vacuum chamber 1 for deflecting electron produced by the electron gun 3.

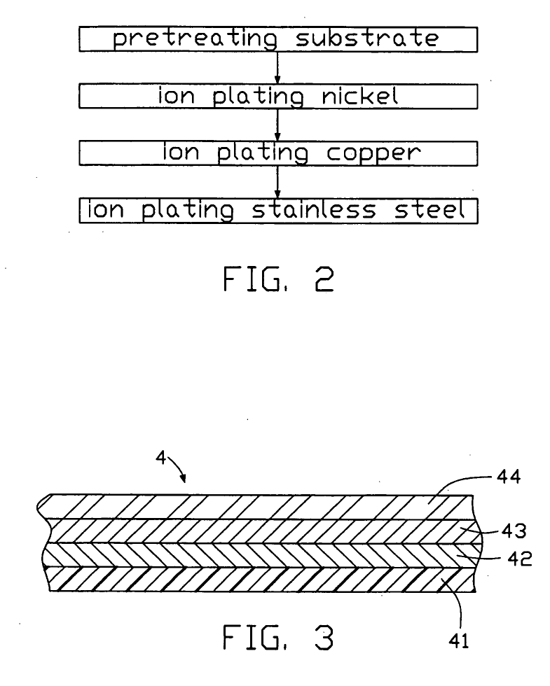

Referring also to FIGS. 2 and 3, a method in accordance with the present invention for manufacturing an EMI-shielding PCB 4 will be described as follows.

The substrate 41 is pretreated before ion-plating with shielding metal. Firstly, the substrate 41 is immersed into an alkaline aqueous solution containing 5% sodium hydroxide (NaOH) by weight at a temperature of 70 to 80 degrees Celsius (° C.), and a wave generator is used to produce ultrasonic waves propagating in the alkaline aqueous solution to degrease the substrate 41. The ultrasonic waves have a frequency of 20 to 40 kilohertz (KHz). After that, the substrate 41 is cleaned several times using hot water having a temperature of 60 to 80° C. The substrate 41 is then dried.

Next, the dried substrate 41 is placed into the vacuum chamber 1, and oxygen plasma is used to clean the same. The substrate 41 then undergoes a glow discharge cleaning step, wherein the vacuum chamber is pumped to a pressure between 1×10⁻¹ and 1×10⁻² Torr. Oxygen gas is introduced into the vacuum chamber 1 via the gas inlet 10 at a volumetric flow rate between 200 and 2000 standard cubic centimeters per minute (SCCM). A high power from the power source 12 having a magnitude of 1 to 3 kilovoltage (Kv) is applied to the substrate 41. The oxygen gas is glowe-discharged into a great amount of oxygen ions. The accelerated oxygen ions impact the substrate for cleaning under the action of the high voltage. This cleaning process lasts for 12 to 20 minutes.

After that, the oxygen gas is no longer introduced into the vacuum chamber 1. The vacuum pump is actuated to drain unreacted oxygen gas from the vacuum chamber 1 and, at the same time, a predetermined amount of argon gas is introduced via the gas inlet 10 into the vacuum chamber 1. Five minutes later, the gas inlet 10 is closed and the vacuum chamber 1 is continued to be pumped by the vacuum pump until it reaches a pressure of 1×10⁻⁶ to 1×10⁻⁸ Torr.

Then, the substrate 41 is coated with a layer of metal material, such as nickel and phosphorus nickel, using an ion-plating method to increase adhesion between the metal and the surface of the substrate 41. The process for ion-plating will be described in details as follows. Firstly, a magnitude of power range from 50 to 200 voltages is applied to the substrate 41. Secondly, argon gas is introduced via the cartrige 32 of the electron gun 3 into the vacuum chamber 1, a volumetric flow rate of argon gas is maintained in the range of 20˜60 SCCM, and a volumetric flow rate of air bleed is maintained at 70˜150 SCCM. Thirdly, the elctron gun 3 is actuated to produce electron beams with high energy and the electron beams are glow-discharged into plasma electron beams under the action of the power source 35. The plasma electron beams are deflected under the action of the magnetic field and impacts the nickel 17 contained in the crucible 15. The nickel 17 is then evaporated and, during atoms of the nickel 17 is migrated through the electron beams toward the substrate 41, some of the atoms of the nickel 17 are bumped against the electron beams to be ionized. In the meantime, a great amount of neutral particles with high energy originated from nickel 17 is also formed and deposited on the surface of the substrate 41 to form a layer of nickel 42 which has a thickness of 5×10⁻⁹ to 10×10⁻⁹ meters, as shown in FIG. 3.

Next, the substrate 41 with a nickel layer thereon is ion plated with copper material using the same method. The copper 18 contained in the crucible 16 is evaporated by electron beams produced by the electron gun 3 and is then ionized. At the same time, a great amount of copper neutral particles with high energy is also formed and deposited on the surface of the substrate 41 to form a layer of copper 43 which has a thickness of 3×10⁻⁷ to 6×10⁻⁷ meters, as shown in FIG. 3.

Finally, a layer of corrosion-resistant layer 44 is selectively plated on the surface of the copper layer of the substrate 41 to form the EMI-shielding PCB 4, using the same ion-plating method. The corrosion-resistant layer 44 is made of corrosion-resistant metal materials, for example, stainless steel. The corrosion-resistant layer 44 has a thickness in the range between 2×10⁻⁸ and 20×10⁻⁸ meters. During the process of ion-plating, the temperature of the substrate should be maintained below 80° C. The EMI-shielding PCB 4 is thus manufactured by the ion-plating method, as shown in FIG. 3, and has superb characteristics of EMI-shielding and improved corrosion resistance.

It is understandable that the above ion-plating process for manufacturing the EMI-shielding PCB 4 is also applicable to make EMI-shielding components and assemblies in cellular phones, note books, and personal digital assistants (PDAs). To obtain better shielding result, a plurality of different metal layers can be plated onto the substrate using the ion-plating method. During the process of ion-plating, the ionized positive ions, which are bumped against the neutral particles with high energy and are under the action of a negative power applied to the substrate, impact the surface of a film layer of the metal to clean atoms which do not firmly adhere to the film layer. As a result, a firm adhesion between the film layer and the substrate is thus formed. Particularly, this method is very suitable for making some EMI-shielding objects which have irregular shapes due to inherent characteristics of the ion-plating method.

It is believed that the present invention and its advantages will be understood from the foregoing description, and it will be apparent that various changes may be made thereto without departing from the spirit and scope of the invention or sacrificing all of its material advantages. Accordingly, the examples hereinbefore described are to be understood as being preferred or exemplary embodiments of the invention.

1. A method for manufacturing an EMI-shielding assembly having a substrate comprising the steps of:
(a) providing oxygen plasma to clean the substrate;
(b) ion plating the cleaned substrate with an adhesion layer;
(c) ion plating the plated substrate with a metal shielding layer; and
(d) ion plating the plated substrate with a corrosion-resistant layer.

2. The method of claim 1, wherein the temperature of the substrate should be maintained below 80° C. during the process of ion-plating.

3. The method of claim 1, wherein the vacuum pressure is maintained between 1×10−6 and 1×10−8 Torr during the process of ion-plating.

4. The method of claim 1, wherein step (a) is processed in a vacuum chamber, and oxygen gas is introduced into the vacuum chamber at a volumetric flow rate of between 200 and 2000 standard cubic centimeters per minute (SCCM).

5. The method of claim 1, wherein in step (b) the adhesion layer is made of nickel or phosphorus nickel.

6. The method of claim 5, wherein in step (c) the metal shielding layer is made of copper.

7. The method of claim 6, wherein in step (d) the corrosion-resistant layer is made of stainless steel.

8. The method of claim 1, wherein the plated substrate is selectively ion plated with a layer of nickel or phosphorus nickel.

9. The method of claim 8, wherein the plated substrate is ion plated with a layer of copper on the nickel or phosphorus nickel layer.

10. A method for manufacturing an EMI-shielding assembly having a substrate comprising the steps of:
(a) cleaning the substrate;
(b) ion plating the cleaned substrate with an adhesion layer made of a first metal material; and
(c) ion plating the plated substrate with a shielding layer made of a second metal material.

11. The method of claim 10, wherein after the step (c), the substrate is ion plated with a corrosion-resistant layer comprising stainless steel.

12. The method of claim 10, wherein in step (a), the substrate is cleaned using oxygen plasma.

13. The method of claim 10, wherein the first metal material is nickel and the second metal material is copper.

14. An EMI-shielding assembly, comprising:
a substrate made of plastic material;
an adhesion layer applied to the substrate;
a metal shielding layer adhered to the adhesion layer of the substrate; and
a corrosion-resistant layer adhered to the metal shielding layer.

15. The EMI-shielding assembly of claim 14, wherein the adhesion layer is made of nickel.

16. The EMI-shielding assembly of claim 14, wherein the adhesion layer is made of phosphorus nickel.

17. The EMI-shielding assembly of claim 15 or claim 16, wherein the adhesion has a thickness of 5×10−9 to 10×10−9 meters.

18. The EMI-shielding assembly of claim 14, wherein the metal shielding layer is made of copper.

19. The EMI-shielding assembly of claim 18, wherein the metal shielding layer has a thickness of 3×10−7 to 6×10−7 meters.

20. The EMI-shielding assembly of claim 14, wherein the corrosion-resistant layer is made of stainless steel and has a thickness in the range of 2×10−8 and 20×10−8 meters.

21. The EMI-shielding assembly of claim 14, wherein said adhesion layer is made of metal.
